(19) United States
(12) Patent Application Publication
(10) Pub. No.: US 2024/0166469 A1
(43) Pub. Date: May 23, 2024

(54) BRAKE DEVICE AND TOWER LIFT COMPRISING THE BRAKE DEVICE

(71) Applicant: SEMES CO., LTD., Chungcheongnam-do (KR)

(72) Inventors: Nahyun LEE, Ansan-si (KR); Myungjin LEE, Hwaseong-si (KR); Namho CHUNG, Seoul (KR); Doohyun BAEK, Hwaseong-si (KR)

(21) Appl. No.: 18/386,652

(22) Filed: Nov. 3, 2023

(30) Foreign Application Priority Data
Nov. 18, 2022 (KR) 10-2022-0155816

(51) Int. Cl. B66B 5/22

(52) U.S. Cl. CPC B66B 5/22

(57) ABSTRACT

A tower lift includes a rail module extending in a vertical direction, a carriage module configured to be movable along the rail module by a magnetic levitation method, and a brake device configured to move along the rail module integrally with the carriage module, wherein the brake device includes a first brake body and a second brake body, which are configured to selectively come into contact with the rail module to prevent the carriage module from falling, and a link unit configured to connect the first brake body to the second brake body, and the link unit transfers force from one of the first brake body and the second brake body to the other of the first brake body and the second brake body.

### CROSS-REFERENCE TO RELATED APPLICATION

This application is based on and claims priority under 35 U.S.C. § 119 to Korean Patent Application No. 10-2022-0155816, filed on Nov. 18, 2022, in the Korean Intellectual Property Office, the disclosure of which is incorporated by reference herein in its entirety.

### BACKGROUND

### 1. Field

The present disclosure relates to a tower lift including a brake device.

### 2. Description of the Related Art

In general, a manufacturing line of a semiconductor or display manufacturing plant is composed of multiple layers. Facilities for performing processes such as deposition, exposure, etching, ion injection, and cleaning may be arranged on the respective layers of a semiconductor manufacturing line. The facilities on the respective layers may repeatedly perform a series of unit processes on a semiconductor wafer being used as a semiconductor substrate or a glass substrate being used as a display substrate.

In addition, the conveyance of articles between the respective layers of the semiconductor manufacturing line, that is, the conveyance of articles such as semiconductor wafers or glass substrates, may be performed by a tower lift installed in a vertical direction through each layer.

A general tower lift includes a carriage module for conveying articles and a rail module for guiding the carriage module in a vertical direction. A driving belt, such as a timing belt, for elevating the carriage module is installed on a rail module. The timing belt is combined with the carriage module to move the carriage module in the vertical direction. However, when the timing belt of such a general tower lift is driven, particles may be generated. For example, the timing belt is driven by friction with a pulley, and while the timing belt rubs against the pulley, particles may be generated.

In order to solve this problem, a method may be considered in which a carriage module moves along a rail module by a magnetic levitation method. The carriage module may be moved in a vertical direction, without coming into contact with the rail module, and while suspended in the air, by the power generated by a linear motor installed on the carriage module or the rail module. In a tower lift in which a carriage module moves along a rail module by a magnetic levitation method, members physically connected to the carriage module, such as a timing belt or a rope, do not exist in the rail module. Accordingly, when power for driving the tower lift is disconnected, the carriage module of the tower lift falls (freely falls).

### SUMMARY

The present disclosure provides a tower lift and a brake unit that may prevent the free fall of a carriage module when power is not applied to the tower lift.

In addition, objects to be achieved by the present disclosure is not limited to the object described above, and other objects may be clearly understood by those skilled in the art from the descriptions below.

Additional aspects will be set forth in part in the description which follows and, in part, will be apparent from the description, or may be learned by practice of the presented embodiments of the disclosure.

According to an aspect of the present disclosure, a tower lift includes a rail module extending in a vertical direction, a carriage module configured to be movable along the rail module by a magnetic levitation method, and a brake device configured to move along the rail module integrally with the carriage module, wherein the brake device includes a first brake body and a second brake body, which are configured to selectively come into contact with the rail module to prevent the carriage module from falling, and a link unit configured to connect the first brake body to the second brake body, and the link unit transfers force from one of the first brake body and the second brake body to the other of the first brake body and the second brake body.

In addition, the first brake body may be apart from the second brake body with the rail module therebetween and faces the second brake body.

In addition, the link unit may include a link member apart in the vertical direction from the first brake body and the second brake body, and a fixing member arranged on a central axis of the link unit.

In addition, the fixing member may be configured to fix part of the link member, and the link member may be configured to rotate around the fixing member.

In addition, the brake device may further include a first base body adjacent to an inclined surface of the first brake body and providing a movement path for the first brake body, and a second base body adjacent to an inclined surface of the second brake body and providing a movement path for the second brake body.

In addition, each of the first brake body and the second brake body may be configured to be movable in an inclined direction with respect to the vertical direction, the first brake body may include a first brake pad on a surface facing the rail module, and the second brake body may include a second brake pad on a surface facing the rail module.

In addition, the brake device may include an electromagnet that is under the first brake body and configured to provide magnetic force to the first brake body.

In addition, an electromagnet providing magnetic force to the second brake body may not be arranged under the second brake body.

In addition, when power is applied to the electromagnet from a power supply, the electromagnet may pull the first brake body.

In addition, the brake device may include a tension member configured to move the second brake body in an inclined direction with respect to the vertical direction and cause the second brake body to come into contact with the rail module when the power applied to the electromagnet from the power supply is not applied to the tension member.

According to another aspect of the present disclosure, a brake device includes a first brake body and a second brake body, which are configured to selectively come into contact with a rail module, prevent a carriage module from falling and, be movable in an inclined direction with respect to a vertical direction, an electromagnet arranged under the first brake body and configured to pull the first brake body, and a link unit configured to connect the first brake body to the second brake body and transfer tension from the first brake body to the second brake body, wherein the link unit includes a link member apart from the first brake body and the second brake body in the vertical direction, a first connection portion configured to connect the link member to the first brake body, a second connection portion configured to connect the link member to the second brake body, and a fixing member arranged on a central axis of the link member, and the first brake body and the second brake body move in opposite directions from each other.

In addition, a movement direction of the first connection portion may be opposite to a movement direction of the second connection portion.

In addition, when power is applied to the electromagnet from a power supply, the electromagnet may provide magnetic force to the first brake body to pull the first brake body, and when the power is not applied to the electromagnet, the electromagnet may not provide the magnetic force to the first brake body, the first connection portion may push up one side of the link member in the vertical direction, and the second connection portion may descend in the vertical direction.

In addition, the brake device may further include a tension member configured to move the second brake body in an inclined direction with respect to the vertical direction and causes the second brake body to come into contact with the rail module when power is not applied to the electromagnet from a power supply.

In addition, the tension member may provide tensile force to the second brake body, and when the power is applied to the electromagnet from the power supply, the electromagnet may provide magnetic force greater than the tensile force to the first brake body.

In addition, each of the first connection portion and the second connection portion may include a body portion configured to transfer the tension and a joint portion coupled to both sides of the body portion.

In addition, the first brake body may include a first brake pad on a surface facing the rail module, the second brake body may include a second brake pad on a surface facing the rail module, the first brake pad and the second brake pad may come into contact with the rail module when power is not applied to the electromagnet from a power supply, and a movement direction of the first brake pad may be opposite to a movement direction of the second brake pad.

According to another aspect of the present disclosure, a tower lift includes a rail module extending in a vertical direction, a carriage module configured to be movable along the rail module by a magnetic levitation method, and a brake device configured to move along the rail module integrally with the carriage module, wherein the brake device includes a first brake body and a second brake body, which are configured to selectively come into contact with the rail module to prevent the carriage module from falling, an electromagnet arranged under the first brake body and configured to provide magnetic force to the first brake body, and a link unit configured to connect the first brake body to the second brake body and transfer tension from the first brake body to the second brake body, the link unit includes a link member apart from the first brake body and the second brake body in the vertical direction, a first connection portion configured to connect the link member to the first brake body, a second connection portion configured to connect the link member to the second brake body, and a fixing member arranged on a central axis of the link member, and the first brake body and the second brake body move in opposite directions from each other.

In addition, the link unit may rotate around the fixing member to transfer the tension from the first brake body to the second brake body.

In addition, the brake device may further include a tension member configured to move the second brake body in an inclined direction with respect to the vertical direction and causes the second brake body to come into contact with the rail module when power is not applied to the electromagnet from a power supply, wherein the tension member may provide tensile force to the second brake body, and the electromagnet may provide magnetic force greater than the tensile force to the first brake body when the power is applied to the electromagnet from the power supply.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view schematically illustrating a state of a semiconductor manufacturing line in which a tower lift is installed, according to an embodiment;

FIG. 2 is a perspective view illustrating a rail module and a carriage module of a tower lift according to an embodiment;

FIG. 3 is a plan view illustrating a rail module and a carriage module of a tower lift according to an embodiment;

FIG. 4 is a view illustrating a brake device and a link unit, according to an embodiment;

FIG. 5 is a view illustrating a brake device and a link unit according to an embodiment;

FIGS. 6 and 7 are views illustrating a state in which the brake device of FIG. 4 applies a brake to a carriage module falling along a rail module; and

FIGS. 8 and 9 are views illustrating states in which a first brake body and a second brake body of FIG. 4 are moved to their original positions respectively by a first recovery member and a second recovery member.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments are described in detail with reference to the accompanying drawings. However, the present disclosure does not have to be configured as limited to the embodiments described below and may be embodied in various other forms. Following examples are provided to fully transfer the scope of the present disclosure to those skilled in the art to which the present disclosure belongs, rather than to enable the present disclosure to be fully completed.

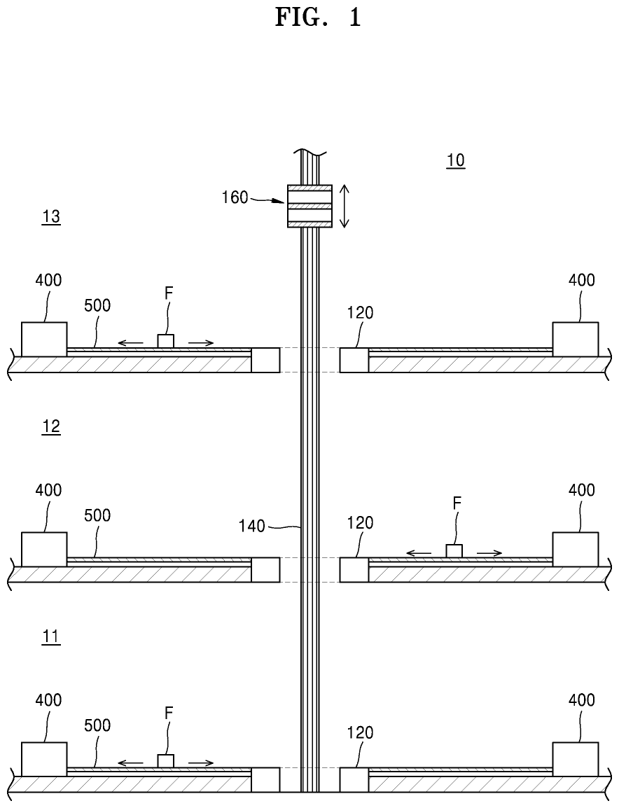

FIG. 1 is a view schematically illustrating a state of a semiconductor manufacturing line in which a tower lift is installed, according to an embodiment.

Referring to FIG. 1, a semiconductor manufacturing line 10 may have a multilayer structure. For example, the semiconductor manufacturing line 10 may include a first layer 11, a second layer 12, and a third layer 13. However, the semiconductor manufacturing line 10 is not limited thereto, and the multilayer structure of the semiconductor manufacturing line 10 may be modified in various ways.

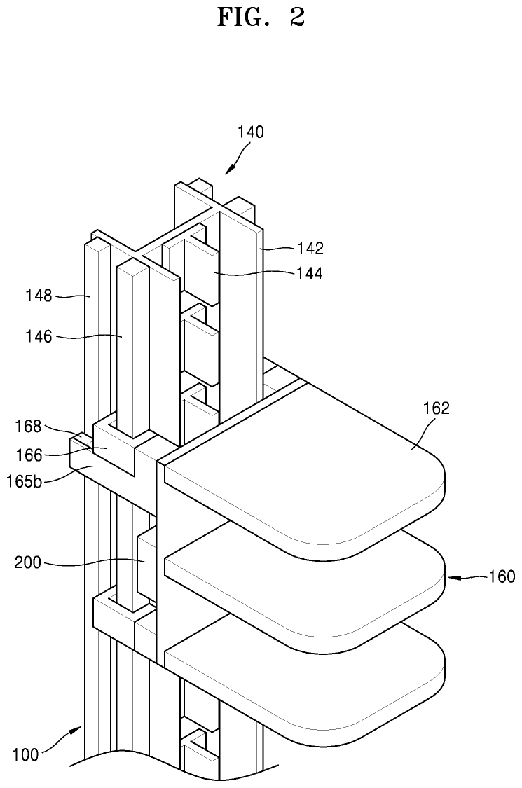

The semiconductor manufacturing line 10 may be provided with a tower lift 100 (see FIG. 2), container storages 400, conveyance rails 500, and a semiconductor manufacturing device (not illustrated) that performs a semiconductor manufacturing process.

The tower lift 100 may convey a container F containing an article to each of the first layer 11, the second layer 12, and the third layer 13 of the semiconductor manufacturing line 10. The tower lift 100 may include stage modules 120, a rail module 140, and a carriage module 160.

The stage modules 120 may be installed respectively on the bottoms of the first layer 11, the second layer 12, and the third layer 13 of the semiconductor manufacturing line 10. The stage modules 120 may be coupled respectively to the conveyance rails 500 that each convey the container F to each of the container storages 400. When the tower lift 100 conveys the containers F respectively to the first layer 11, the second layer 12, and the third layer 13, the containers F may be respectively conveyed to the container storages 400 by the conveyance rails 500.

The rail module 140 may extend in a vertical direction. The rail module 140 may extend vertically between at least two layers of the semiconductor manufacturing line 10. The rail module 140 may guide the movement of the carriage module 160 to be described below. In addition, the rail module 140 may move the carriage module 160 to be described below in the vertical direction.

The carriage module 160 (an example of a moving body) may be movable along the rail module 140. For example, the carriage module 160 may be movable along the rail module 140 in the vertical direction. The carriage module 160 may include a carriage 162 that carries an article. A plurality of carriage modules 160 may be provided. For example, the number of carriage modules 160 may be variously modified.

The carriage module 160 may include a shelf on which the container F containing an article is safely placed. Alternatively, the carriage module 160 may also include a robot that holds the container F. The carriage module 160 may be modified into various structures that may move the container F.

Hereinafter, the rail module 140 and the carriage module 160 according to an embodiment are described in detail.

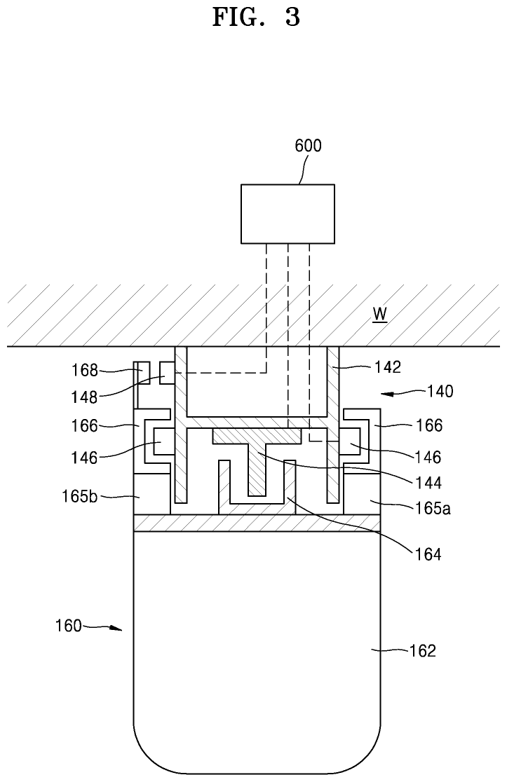

FIG. 2 is a perspective view illustrating the rail module 140 and the carriage module 160 of the tower lift 100 according to the embodiment. FIG. 3 is a cross-sectional view illustrating the rail module 140 and the carriage module 160 of the tower lift 100 according to the embodiment.

Referring to FIGS. 2 and 3, the rail module 140 may include a frame 142, a linear motor coil 144, a guide rail 146, and a power transmitter 148.

The frame 142 may extend in the vertical direction. A longitudinal direction of the frame 142 may be the vertical direction. The frame 142 may be fixedly installed on a wall W of the semiconductor manufacturing line 10. The linear motor coil 144, the guide rail 146, and the power transmitter 148 to be described below may be coupled to the frame 142. The frame 142 may have an ‘H’ shape as a whole when viewed from above, but is not limited thereto, and a shape of the frame 142 may be variously modified.

The linear motor coil 144 may move the carriage 162 in the vertical direction by interaction with a linear motor magnet 164 to be described below. The interaction may be due to magnetic force generated by the linear motor coil 144 and/or the linear motor magnet 164. The linear motor coil 144 may be installed on the frame 142. When viewed from above, the linear motor coil 144 may be installed on a surface of the frame 142 facing the carriage module 160.

Also, an interface line (not illustrated), such as a power line may be connected to the linear motor coil 144. In addition, a pair of linear motor coils 144 may be provided in plurality. The pair of linear motor coils 144 provided in plurality may be installed on the frame 142 so as to be separated from each other in the vertical direction in which the frame 142 extends.

The guide rail 146 may restrict a part of the degree of freedom of the carriage module 160. For example, the guide rail 146 may restrict the degree of freedom in a horizontal direction except for the degree of freedom of movement of the carriage module 160 in the vertical direction. The guide rail 146 may be separated from the guide portion 166 of the carriage module 160 to be described below due to a repulsive force by a magnetic force. An interface line (not illustrated), such as a power line, may be connected to the guide rail 146. In addition, a gap sensor (not illustrated) may be provided to any one of the guide rail 146 and the guide portion 166, and the magnetic force may be controlled based on a measurement value measured by the gap sensor. Accordingly, a distance between the guide rail 146 and the guide portion 166 may be controlled to be substantially constant.

At least one guide rail 146 may be provided. For example, a plurality of guide rails 146 may be provided. One of the plurality of guide rails 146 may be installed on one surface of the frame 142, and another of the plurality of guide rails 146 may be installed on the other surface of the frame 142. For example, one of the plurality of guide rails 146 may be installed on one sidewall of the frame 142, and another of the plurality of guide rails 146 may be installed on the other sidewall of the frame 142. In addition, a longitudinal direction of the guide rail 146 may be the same as a longitudinal direction of the frame 142.

The power transmitter 148 may transmit power to the power receiver 168 of the carriage module 160 to be described below. For example, the power transmitter 148 may be any one of high efficiency inductive power distribution technology (HID) devices that supply power in a non-contact manner. The power transmitter 148 may be installed on the frame 142. The power transmitter 148 may be installed on any one of surfaces of the frame 142 on which the guide rail 146 is installed. For example, the power transmitter 148 may be installed on one sidewall of the surfaces of the frame 142 on which the guide rail 146 is installed. An interface line (not illustrated), such as a power line, may be connected to the power transmitter 148.

The carriage module 160 may convey the container F containing an article. The carriage module 160 may be moved in the vertical direction along the rail module 140. The carriage module 160 may be moved in the vertical direction along the rail module 140 to convey the container F containing an article to the first layer 11, the second layer 12, and the third layer 13 of the semiconductor manufacturing line 10. The carriage module 160 may include the carriage 162, the linear motor magnet 164, connection bodies 165a and 165b, the guide portion 166, and the power receiver 168.

The carriage 162 may have a shelf shape on which the container F containing an article is contained may be safely placed. A robot (not illustrated) may be provided on the carriage 162 to hold the container F containing an article. Although FIG. 2 illustrates that the carriage 162 has a shape of a three-stage shelf, the carriage 162 is not limited thereto, and the shape of the carriage 162 may be variously modified.

The linear motor magnet 164 may be coupled to the carriage 162. The linear motor magnet 164 may move the carriage 162 in the vertical direction by interaction with the linear motor coil 144 described above. The interaction may be due to magnetic force generated by the linear motor coil 144 and/or the linear motor magnet 164. A part of the linear motor coil 144 may be inserted into an open portion of the linear motor magnet 164.

The connection bodies 165a and 165b may couple the guide portion 166 to be described below and the power receiver 168 to the carriage 162. The connection bodies 165a and 165b may include a first connection body 165a and a second connection body 165b. The first connection body 165a and the second connection body 165b may have different shapes. The second connection body 165b may couple the guide portion 166 and the power receiver 168 to the carriage 162. The first connection body 165a may couple the guide portion 166 to the carriage 162.

The guide portion 166 may be coupled to the carriage 162 by the connection bodies 165a and 165b. Accordingly, when the carriage 162 is moved, the guide portion 166 may move along with the carriage 162 in the vertical direction. The guide portion 166 may have a shape surrounding at least a part of the guide rail 146 installed on the frame 142. The guide rail 146 may be inserted into the guide portion 166.

The guide portion 166 and the guide rail 146 may restrict the remaining degree of freedom except for the degree of freedom of vertical movement of the carriage module 160. In addition, a gap sensor (not illustrated) may be provided to any one of the guide rail 146 and the guide portion 166 and may control the magnetic force based on a measurement value measured by the gap sensor. Accordingly, a distance between the guide rail 146 and the guide portion 166 may be controlled to be substantially constant.

The power receiver 168 may receive the power transmitted from the power transmitter 148. In addition, the power receiver 168 may be installed to face the power transmitter 148. The power receiver 168 may be any one of HID devices that supply power in a non-contact manner. The power receiver 168 may be coupled to the carriage 162 via the second connection body 165b. Accordingly, when the carriage 162 is moved, the power receiver 168 may be moved along with the carriage 162 in the vertical direction.

The carriage module 160 according to an embodiment may include the linear motor magnet 164, and the linear motor magnet 164 may move the carriage 162 to the rail module 140 by interacting with the linear motor coil 144. That is, the carriage module 160 according to an embodiment may move along the rail module 140 by a magnetic levitation method. In the typical tower lift, a carriage module is moved by friction between a timing belt and a pulley, and in this case, particles may be generated. However, the carriage module 160 according to an embodiment may move along the rail module 140 by a magnetic levitation method. Accordingly, the problem of generating particles may be greatly reduced.

In addition, the carriage module 160 may include the power receiver 168 and receive power from the power transmitter 148 in a non-contact manner. That is, power required to drive the carriage module 160 may be received in a non-contact manner. In addition, according to the present disclosure, the linear motor coil 144 requiring power line connection may be installed in the frame 142, and the carriage module 160 may include the linear motor magnet 164 that does not require power line connection. That is, interface lines, such as power lines, may all be connected to components of the rail module 140, and the interface lines may not be connected to the carriage module 160. When interface lines are connected to the carriage module 160, the connected interface lines may function as components that hinder operations of the plurality of carriage modules 160, and because the carriage module 160 according to an embodiment is not connected to the interface lines, the operations of the plurality of carriage modules 160 may be easily performed.

In addition, a pair of linear motor coils 144 included in the rail module 140 may be provided in plurality and may be installed on the frame 142 to be separated from each other in a longitudinal direction of the frame 142.

The controller 600 may control the tower lift 100. The controller 600 may control the tower lift 100 such that the carriage module 160 moves along the rail module 140 by a magnetic levitation method. In addition, the controller 600 may include a process controller composed of a microprocessor (a computer) that controls the tower lift 100, a user interface composed of a keyboard for an operator to input commands and so on to manage the tower lift 100, a display for visualizing and displaying an operation status of the tower lift 100, and so on and, a storage that stores a control program for performing processing of the tower lift 100 under control by a process controller or a program for performing processing of each component according to various data and processing conditions, that is, a processing recipe. Also, the user interface and the storage may be connected to the process controller. The processing recipe may be stored in a storage medium of the storage, and the storage medium may be a hard disk, a portable disk, such as a compact disk-read only memory (CD-ROM) or a digital video disk (DVD), or a semiconductor memory, such as flash memory.

In this way, the carriage module 160 according to an embodiment may be moved along the rail module 140 by a magnetic levitation method. Accordingly, when power for driving the carriage module 160 is not applied to the carriage module 160, the carriage module 160 may fall (free fall). Accordingly, a brake device 200 may be installed in the carriage module 160 of the tower lift 100 according to an embodiment. When power for driving the tower lift 100 is disconnected therefrom, the carriage module 160 may fall, and the brake device 200 may prevent the carriage module 160 from falling even in a state in which power is disconnected.

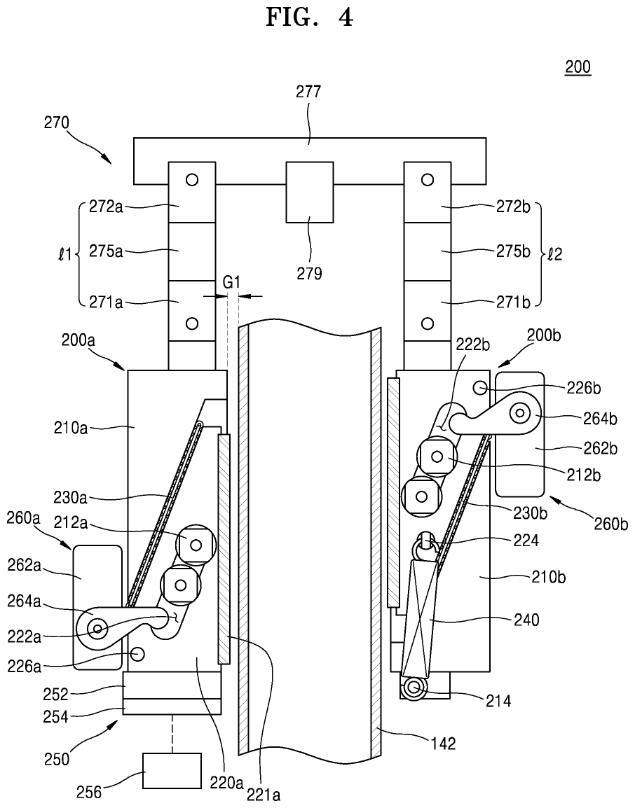

FIG. 4 is a view illustrating the brake device 200 and the link unit 270 according to an embodiment. Specifically, FIG. 4 illustrates a state of the brake device 200 in a state in which power is applied to the tower lift 100.

Referring to FIG. 4, the brake device 200 according to an embodiment may include the link unit 270, a first brake unit 200a, and a second brake unit 200b. The first brake unit 200a may include a first base body 210a, a first brake body 220a, a first sliding roller 230a, a holding member 250, and a first recovery member 260a. The second brake unit 200b may include a second base body 210b, a second brake body 220b, a second sliding roller 230b, a second recovery member 260b, and a tension member 240.

The link unit 270 may connect the first brake body 220a to the second brake body 220b. The link unit 270 may transfer force from one of the first brake body 220a and the second brake body 220b to the other of the first brake body 220a and the second brake body 220b. For example, the link unit 270 may transfer attractive force due to magnetic force from the first brake body 220a to the second brake body 220b. Also, the link unit 270 may transfer attractive force due to tensile force from the second brake body 220b to the first brake body 220a. When receiving power from a power source 256, an electromagnet 252 may provide tensile force greater than tension to the first brake body 220a.

The link unit 270 may include a link member 277, a fixing member 279, a first connection portion 11, and a second connection portion 12. The link member 277 may be vertically separated from the first brake unit 200a and the second brake unit 200b.

The link member 277 may be separated from the first brake body 220a and the second brake body 220b in the vertical direction. The fixing member 279 may be on a central axis of the link member 277. The fixing member 279 may have a shape protruding from the link member 277 in the vertical direction. The fixing member 279 may fix a part of the link member 277. The first connection portion 11 may connect the link member 277 to the first brake body 220a. The second connection portion 12 may connect the link member 277 to the second brake body 220b.

The link member 277 may rotate around the fixing member 279. For example, the link member 277 may rotate clockwise or counterclockwise. A movement direction of the first connection portion 11 may be opposite to a movement direction of the second connection portion 12. For example, when the first connection portion 11 moves upward in the vertical direction, the second connection portion 12 may move downward in the vertical direction. Also, when the first connection portion 11 moves downward in the vertical direction, the second connection portion 12 may move upward in the vertical direction. Here, when power is not applied to the first connection portion 11, the first connection portion 11 may push up one side of the link member 277 in the vertical direction. Also, the second connection portion 12 may descend in the vertical direction.

The first connection portion 11 may include a first body portion 275a, a first joint portion 271a, and a second joint portion 272a. The second connection portion 12 may include a second body portion 275b, a third joint portion 271b, and a fourth joint portion 272b. The first body portion 275a and the second body portion 275b may transfer tension. The first joint portion 271a and the second joint portion 272a may be coupled to both sides of the first body portion 275a. The first joint portion 271a may be closer to the first base body 210a than the second joint portion 272a. The third joint portion 271b and the fourth joint portion 272b may be coupled to both sides of the second body portion 275b. The third joint portion 271b may be closer to the second base body 210b than the fourth joint portion 272b.

Relative positions of the first base body 210a and the second base body 210b may be fixed to the carriage module 160. For example, the first base body 210a and the second base body 210b may be fixedly coupled to the carriage module 160 (see FIG. 3). The first base body 210a may include a plurality of first guide pins 212a that are inserted into a first guide hole 222a to be described below. The second base body 210b may include a plurality of second guide pins 212b that are inserted into a second guide hole 222b to be described below. The first base body 210a may be adjacent to an inclined surface of the first brake body 220a and provide a movement path for the first brake body 220a. The second base body 210b may be adjacent to an inclined surface of the second brake body 220b and provide a movement path for the second brake body 220b.

The first guide pin 212a may guide a movement direction of the first brake body 220b, and the second guide pin 212b may guide a movement direction of the second brake body 220b. The second base body 210b may include a base body hook portion 214. A hook that may be one end of the tension member 240 may be caught and fixed to the base body hook portion 214.

The first brake body 220a and the second brake body 220b may selectively come into contact with the rail module 140, more specifically, the frame 142 of the rail module 140 to prevent the free fall of the carriage module 160. When viewed from the front, the first brake body 220a and the second brake body 220b may have a right triangle shape in which a corner portion including an acute angle is cut.

In addition, the first brake body 220a may include a first brake pad 221a provided on a surface of the first brake body 220a facing the frame 142 of the rail module 140, and the second brake body 220b may include a second brake pad 221b provided on a surface of the second brake body 220b facing the frame 142 of the rail module 140. A distance G1 between the frame 142 and any one of the first brake pad 221a and the second brake pad 221b may be about 3 mm to about 5 mm.

Also, the first guide hole 222a into which the plurality of first guide pins 212a may be inserted may be formed in the first brake body 220a. A second guide hole 222b into which the plurality of second guide pins 212b may be inserted may be formed in the second brake body 220b. The first guide hole 222a may have a long hole shape formed in an upwardly inclined direction toward the frame 142. Also, the second guide hole 222b may have a long hole shape formed in a downwardly inclined direction toward the frame 142. Accordingly, the first brake body 220a and the second brake body 220b may be moved in an inclined direction with respect to the vertical direction. The first brake body 220a may face the second brake body 220b. The first brake body 220a and the second brake body 220b may each be movable in an inclined direction with respect to the vertical direction.

The first sliding roller 230a may be between the first base body 210a and the first brake body 220a. Also, the second sliding roller 230b may be between the second base body 210b and the second brake body 220b. For example, the first sliding roller 230a may be between an inclined surface of the first brake body 220a and the first base body 210a. The second sliding roller 230b may be between an inclined surface of the second brake body 220b and the second base body 210b. When the first brake body 220a moves in an inclined direction, the first sliding roller 230a helps the first brake body 220a to move more smoothly.

When power is not applied the tension member 240, the tension member 240 may move the second brake body 220b in a downwardly inclined direction to cause the second brake body 220b to come into contact with the frame 142 of the rail module 140. The tension member 240 may be composed of a tension spring and two rings connected to the tension spring, one of the two rings is caught and fixed to the base body hook portion 214, and the other of the two rings may be caught and fixed to the body hook portion 224.

The holding member 250 may selectively come into contact with the first brake body 220a with the frame 142 of the rail module 140 by holding the first brake body 220a only when power is applied to the tower lift 100. For example, the holding member 250 may hold the first brake body 220a when power is applied to the tower lift 100 and may not hold the first brake body 220a when power is not applied to the tower lift 100.

Also, the holding member 250 may include an electromagnet 252 and a holding frame 254. The holding frame 254 may fix the electromagnet 252 to the carriage module 160, and a power supply 256 that drives the tower lift 100 may be connected to the electromagnet 252. For example, when the power supply 256 applies power to the tower lift 100 and the first brake unit 200a, the power may be applied to the electromagnet 252.

In this case, the electromagnet 252 may generate magnetic force to hold the first brake body 220a. In this case, the first brake body 220a may be separated from the frame 142 of the rail module 140. The electromagnet 252 may be below the first brake body 220a. Also, the electromagnet 252 may not be below or above the second brake body 220b. Magnetic force may be provided to the first brake body 220a. For example, when power is applied to the electromagnet 252 from the power supply 256, the electromagnet 252 may provide an attractive force (for example, magnetic force) to pull the first brake body 220a.

The first recovery member 260a may move the first brake body 220a. The second recovery member 260b may move the second brake body 220b. For example, the first recovery member 260a may move the first brake body 220a in a downwardly inclined direction. The second recovery member 260b may move the second brake body 220b in an upwardly inclined direction. The first recovery member 260a may include a first actuator 262a and a first recovery body 264a. The second recovery member 260b may include a second actuator 262b and a second recovery body 264b. Each of the first actuator 262a and the second actuator 262b may be a motor.

The first actuator 262a may rotate the first recovery body 264a. The second actuator 262b may rotate the second recovery body 264b. The first recovery body 264a may be on the first brake body 220a. Also, the first recovery body 264a may push down a first recovery protrusion 226a protruding forward to move the first brake body 220a in a downwardly inclined direction. The second recovery body 264b may be on the second brake body 220b. The second recovery body 264b may push down a second recovery protrusion 226b protruding forward to move the second brake body 220b in an upwardly inclined direction.

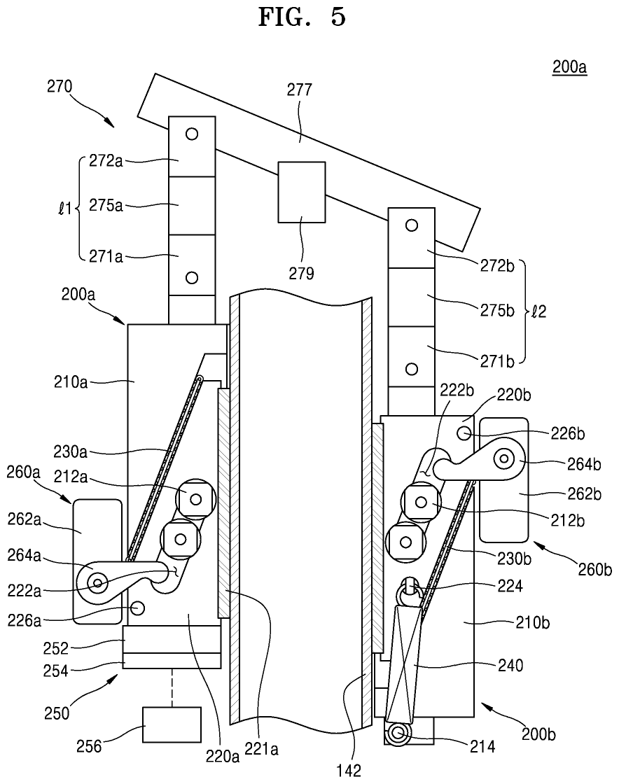

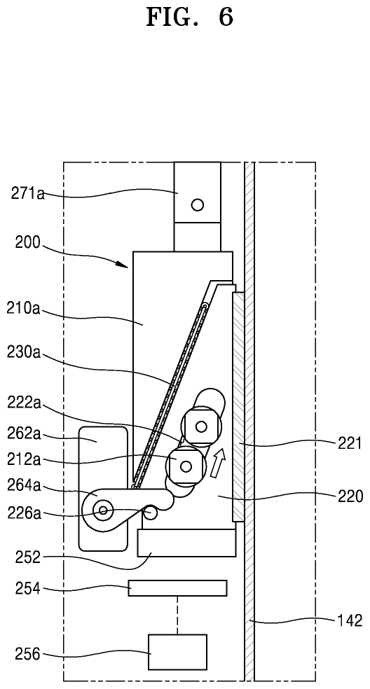

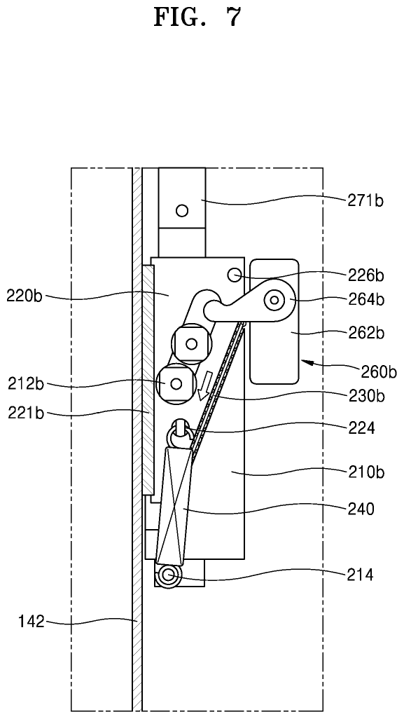

FIG. 5 is a view illustrating the brake device 200 and the link unit 270 according to an embodiment. Specifically, FIG. 5 illustrates a state of the brake device 200 in a state in which power is not applied to the tower lift 100. FIGS. 6 and 7 are views illustrating a state in which the brake device 200 of FIG. 4 applies a brake to the carriage module 160 falling along the rail module 140. Descriptions of FIGS. 6 and 7 are made with reference to FIG. 4, and descriptions previously given with reference to FIG. 4 are briefly made or omitted.

Referring to FIGS. 5 to 7, when power is not applied to the tower lift 100, the power may also be not applied to the electromagnet 252. In this case, the electromagnet 252 does not generate magnetic force, and accordingly, the electromagnet 252 may not hold the first brake body 220a.

The second brake body 220b may be moved in a downwardly inclined direction by the tensile force of the tension member 240. Also, the tensile force of the tension member 240 may be transferred to the first brake body 220a through the link unit 270. That is, the link unit 270 may transfer tension to the first brake body 220a and the second brake body 220b. The first brake body 220a may move in an upwardly inclined direction by the tension of the tension member 240 transferred through the link unit 270.

Accordingly, the first brake pad 221a of the first brake body 220a may come into contact with the frame 142 of the rail module 140, and the second brake pad 221b of the second brake body 220b may come into contact with the frame 142 of the rail module 140. The first brake pad 221a and the second brake pad 221b may provide frictional force to the frame 142 of the rail module 140. Through this, the first brake unit 200a and the second brake unit 200b may prevent the free fall of the carriage module 160.

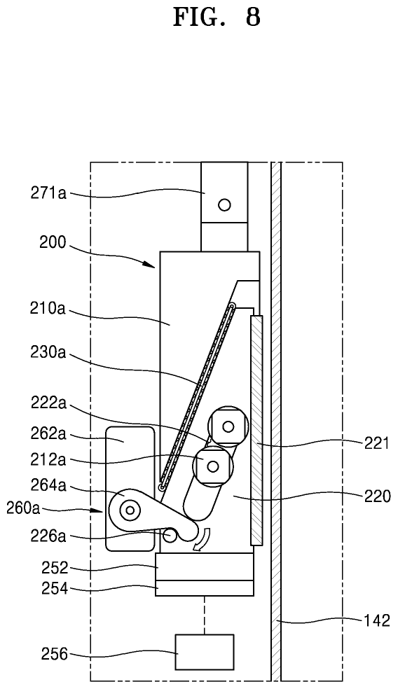

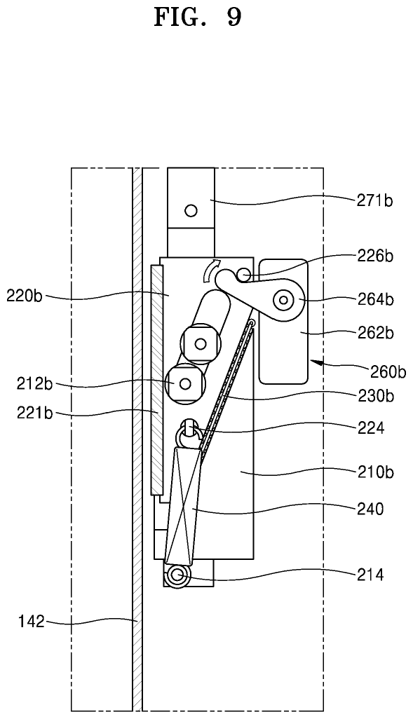

FIGS. 8 and 9 are views illustrating a state in which the first brake body 220a and the second brake body 220b of FIG. 4 are moved to their original positions respectively by the first recovery member 260a and the second recovery member 260b. Descriptions of FIGS. 8 and 9 are made with reference to FIGS. 4 and 5, and descriptions previously given with reference to FIGS. 4 and 5 are briefly made or omitted.

Referring to FIGS. 8 and 9, after the first brake body 220a and the second brake body 220b come into contact with the frame 142 of the rail module 140, power may be applied to the tower lift 100 again.

In this case, the first recovery body 264a of the first recovery member 260a may rotate to move the first brake body 220a in a downwardly inclined direction. Through this, the first recovery member 260a may return the first brake body 220a to an original position of the first brake body 220a. When the first brake body 220a is in the original position, magnetic force of the electromagnet 252 is generated, and thereby, the holding member 250 holds the first brake body 220a again.

Also, while the first brake body 220a moves to the original position, tension for pulling the first connecting portion 414a of the link unit 270 may be generated, and the link unit 270 may transfer the tension to the second brake body 220b. Accordingly, the second recovery body 264b of the second recovery member 260b may rotate to move the second brake body 220a in an upwardly inclined direction. Through this, the second recovery member 260b may return the second brake body 220b to an original position of the second brake body 220b.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A tower lift comprising:
a rail module extending in a vertical direction;
a carriage module configured to be movable along the rail module by a magnetic levitation method; and
a brake device configured to move along the rail module integrally with the carriage module,
wherein the brake device includes a first brake body and a second brake body, which are configured to selectively come into contact with the rail module to prevent the carriage module from falling, and a link unit configured to connect the first brake body to the second brake body, and
the link unit transfers force from one of the first brake body and the second brake body to the other of the first brake body and the second brake body.

2. The tower lift of claim 1, wherein the first brake body is apart from the second brake body with the rail module therebetween and faces the second brake body.

3. The tower lift of claim 1, wherein
the link unit includes a link member apart in the vertical direction from the first brake body and the second brake body; and
a fixing member arranged on a central axis of the link unit.

4. The tower lift of claim 3, wherein
the fixing member is configured to fix part of the link member, and
the link member is configured to rotate around the fixing member.

5. The tower lift of claim 1, wherein the brake device further includes a first base body adjacent to an inclined surface of the first brake body and providing a movement path for the first brake body, and a second base body adjacent to an inclined surface of the second brake body and providing a movement path for the second brake body.

6. The tower lift of claim 1, wherein
each of the first brake body and the second brake body is configured to be movable in an inclined direction with respect to the vertical direction,
the first brake body includes a first brake pad on a surface facing the rail module, and
the second brake body includes a second brake pad on a surface facing the rail module.

7. The tower lift of claim 6, wherein the brake device includes an electromagnet that is under the first brake body and configured to provide magnetic force to the first brake body.

8. The tower lift of claim 7, wherein an electromagnet providing magnetic force to the second brake body is not arranged under the second brake body.

9. The tower lift of claim 7, wherein when power is applied to the electromagnet from a power supply, the electromagnet pulls the first brake body.

10. The tower lift of claim 9, wherein the brake device includes a tension member configured to move the second brake body in an inclined direction with respect to the vertical direction and cause the second brake body to come into contact with the rail module when the power applied to the electromagnet from the power supply is not applied to the tension member.

11. A brake device comprising:
a first brake body and a second brake body, which are configured to selectively come into contact with a rail module, prevent a carriage module from falling, and be movable in an inclined direction with respect to a vertical direction;
an electromagnet arranged under the first brake body and configured to pull the first brake body; and
a link unit configured to connect the first brake body to the second brake body and transfer tension from the first brake body to the second brake body,
wherein the link unit includes a link member apart from the first brake body and the second brake body in the vertical direction, a first connection portion configured to connect the link member to the first brake body; a second connection portion configured to connect the link member to the second brake body, and a fixing member arranged on a central axis of the link member, and
the first brake body and the second brake body move in opposite directions from each other.

12. The brake device of claim 11, wherein a movement direction of the first connection portion is opposite to a movement direction of the second connection portion.

13. The brake device of claim 11, wherein,
when power is applied to the electromagnet from a power supply, the electromagnet provides magnetic force to the first brake body to pull the first brake body, and
when the power is not applied to the electromagnet, the electromagnet does not provide the magnetic force to the first brake body, the first connection portion pushes up one side of the link member in the vertical direction, and the second connection portion descends in the vertical direction.

14. The brake device of claim 11, further comprising a tension member configured to move the second brake body in an inclined direction with respect to the vertical direction and causes the second brake body to come into contact with the rail module when power is not applied to the electromagnet from a power supply.

15. The brake device of claim 14, wherein
the tension member provides tensile force to the second brake body, and
when the power is applied to the electromagnet from the power supply, the electromagnet provides magnetic force greater than the tensile force to the first brake body.

16. The brake device of claim 11, wherein each of the first connection portion and the second connection portion includes: a body portion configured to transfer the tension; and a joint portion coupled to both sides of the body portion.

17. The brake device of claim 11, wherein
the first brake body includes a first brake pad on a surface facing the rail module,
the second brake body includes a second brake pad on a surface facing the rail module,
the first brake pad and the second brake pad come into contact with the rail module when power is not applied to the electromagnet from a power supply, and
a movement direction of the first brake pad is opposite to a movement direction of the second brake pad.

18. A tower lift comprising:
a rail module extending in a vertical direction;
a carriage module configured to be movable along the rail module by a magnetic levitation method; and
a brake device configured to move along the rail module integrally with the carriage module,
wherein the brake device includes a first brake body and a second brake body, which are configured to selectively come into contact with the rail module to prevent the carriage module from falling, an electromagnet arranged under the first brake body and configured to provide magnetic force to the first brake body, and a link unit configured to connect the first brake body to the second brake body and transfer tension from the first brake body to the second brake body,
the link unit includes a link member apart from the first brake body and the second brake body in the vertical direction, a first connection portion configured to connect the link member to the first brake body, a second connection portion configured to connect the link member to the second brake body, and a fixing member arranged on a central axis of the link member, and
the first brake body and the second brake body move in opposite directions from each other.

19. The tower lift of claim 18, wherein the link unit rotates around the fixing member to transfer the tension from the first brake body to the second brake body.

20. The tower lift of claim 18, further comprising:
a tension member configured to move the second brake body in an inclined direction with respect to the vertical direction and causes the second brake body to come into contact with the rail module when power is not applied to the electromagnet from a power supply,
wherein the tension member provides tensile force to the second brake body, and
the electromagnet provides magnetic force greater than the tensile force to the first brake body when the power is applied to the electromagnet from the power supply.
